(19) United States
(12) Patent Application Publication
(10) Pub. No.: US 2010/0260933 A1
(43) Pub. Date: Oct. 14, 2010

(54) APPARATUS AND METHOD FOR THE PRODUCTION OF CARBON NANOTUBES ON A CONTINUOUSLY MOVING SUBSTRATE

(75) Inventors: Harry C. MALECKI, Abingdon, MD (US); James P. LOEBACH, Bel Air, MD (US); Tushar K. SHAH, Columbia, MD (US); Mark R. ALBERDING, Glen Arm, MD (US); Jack K. BRAINE, Columbia, MD (US); John A. LARUE, Bel Air, MD (US)

Correspondence Address: MCDERMOTT WILL & EMERY LLP, 18191 VON KARMAN AVE., SUITE 500, IRVINE, CA, 92612-7108, US

(73) Assignee: Lockheed Martin Corporation, Bethesda, MD (US)

(21) Appl. No.: 12/714,389

(22) Filed: Feb. 26, 2010

Related U.S. Application Data
(60) Provisional application No. 61/168,516, filed on Apr. 10, 2009.
(60) Provisional application No. 61/295,624, filed on Jan. 15, 2010.

(51) Int. Cl. C23C 16/44; C23C 16/00

(52) U.S. Cl. 427/249.1; 118/724; 977/842

(57) ABSTRACT

An apparatus having at least one carbon nanotube growth zone having a substrate inlet sized to allow a spoolable length substrate to pass therethrough. The apparatus also has at least one heater in thermal communication with the carbon nanotube growth zone. The apparatus has at least one feed gas inlet in fluid communication with the carbon nanotube growth zone. The apparatus is open to the atmosphere during operation.

### STATEMENT OF RELATED APPLICATIONS

This application claims priority to U.S. Provisional Application No. 61/168,516 filed Apr. 10, 2009 and to U.S. Provisional Application No. 61/295,624 filed Jan. 15, 2010, which are incorporated herein by reference in their entirety.

### STATEMENT REGARDING FEDERALLY SPONSORED RESEARCH OR DEVELOPMENT

Not applicable.

### FIELD OF THE INVENTION

The present invention relates in general to an apparatus and method for the production of carbon nanotubes on a continuously moving substrate.

### BACKGROUND OF THE INVENTION

As used herein, the term “carbon nanotube” (CNT, plural CNTs) refers to any of a number of cylindrically-shaped allotropes of carbon of the fullerene family including single-walled carbon nanotubes (SWNTs), double-walled carbon nanotubes (DWNTs), multi-walled carbon nanotubes (MWNTs). CNTs can be capped by a fullerene-like structure or open-ended. CNTs include those that encapsulate other materials. Carbon nanotubes exhibit impressive physical properties. The strongest CNTs exhibit roughly eighty times the strength, six times the toughness (i.e., Young's Modulus), and one-sixth the density of high carbon steel.

Current carbon nanotube (CNT) synthesis techniques can provide bulk quantities of “loose” CNTs for use in a variety of applications. These bulk CNTs can be used as a modifier or dopant in composite systems, for example. Such modified composites typically exhibit enhanced properties that represent a small fraction of the theoretical improvements expected by the presence of CNTs. The failure to realize the full potential of CNT enhancement is related, in part, to the inability to dope beyond low percentages of CNTs (1-4%) in the resulting composite along with an overall inability to effectively disperse the CNTs within the structure. This low loading, coupled with difficulties in CNT alignment and CNT-to-matrix interfacial properties figure in the observed marginal increases in composite properties, such as mechanical strength, compared to the theoretical strength of CNTs. Besides the physical limitation of bulk CNT incorporation, the price of CNTs remain high due to process inefficiencies and post processing required to purify the end CNT product.

One approach to overcome the above deficiencies, would be to develop techniques that grow CNTs directly on useful substrates, such as fibers, which can be used to organize the CNTs and provide a reinforcing materials in a composite. Attempts have been made to grow CNTs in a nearly continuous fashion, however, none have been successful such that they operate continuously, roll to roll without batch-wise processing. The present invention provides an apparatus and method that allows for continuous production of CNTs on a variety of substrates and provides related advantages as well.

Some processes attempt to grow CNTs directly on fiber substrates; illustrative thereof is the process disclosed in U.S. Pat. No. 7,338,684 to Curliss et al. This patent discloses a method for producing vapor-grown carbon-fiber-reinforced composite materials. According to the patent, a catalyst precursor such as a ferric nitrate solution is applied as a coating to fiber preform. The coated preform is then heated in air, typically at a temperature in the range of 300° C. to 800° C., to decompose the precursor and yield an oxidized catalyst particle. Some of the examples disclose a heating time of 30 hrs. To reduce the catalyst particle to a metallic state, the preform is exposed to a flowing gas mixture including hydrogen. This is typically performed at a temperature of 400° C. to 800° C. for a period of time in the range of about 1 hour to about 12 hours.

Vapor grown carbon fiber (i.e., CNTs) is produced by contacting a gas phase hydrocarbon gas mixture with the preform at a temperature between about 500° C. to 1200° C. According to the patent, the fibers grow on the composite preform resulting in a tangled mass of carbon fiber (carbon nanotubes). The reaction time for growth varies between 15 minutes and 2 hours, primarily as a function of feed gas composition and temperature.

The processing times for the approach disclosed in U.S. Pat. No. 7,338,684 are too long for efficient processing. Furthermore, due to the extreme variation in the processing time for various steps, the process is unsuitable for implementation as a continuous processing line for the production of carbon nanotubes on a continuously moving substrate.

### SUMMARY OF THE INVENTION

In some aspects, embodiments disclosed herein relate to an apparatus capable of linear and/or continuous CNT synthesis on spoolable length substrates. The apparatus includes at least one carbon nanotube growth zone having a substrate inlet sized to allow a spoolable length substrate to pass therethrough The apparatus also includes at least one heater in thermal communication with the carbon nanotube growth zone; and at least one feed gas inlet in fluid communication with the carbon nanotube growth zone. The apparatus is open to the atmosphere during operation. The CNT growth is carried out at ambient or near ambient pressures. The apparatus optionally includes one or more purge zones, on opposing sides of the carbon nanotube growth zone. The apparatus is designed to be integrated into a system for the continuous growth of carbon nanotubes.

### BRIEF DESCRIPTION OF THE DRAWINGS

FIG. 1 shows a simplified perspective view of an apparatus for the synthesis of CNTs in a continuous process in accordance with an embodiment of the present invention.

FIG. 2 shows a simplified cross-sectional side view of an apparatus for the synthesis of CNTs in a continuous process in accordance with an illustrative embodiment of the present invention.

FIG. 3 shows a cross-sectional side view of an embodiment of an apparatus in accordance with the present invention.

FIG. 4 shows a cross-sectional side view of an embodiment of an apparatus in accordance with the present invention.

FIG. 5 shows a top cross-sectional view of the apparatus of FIG. 3 in accordance with the present invention.

FIG. 6 shows a top cross-sectional view of an embodiment of an apparatus in accordance with the present invention.

FIG. 7 shows a transverse side view of another embodiment of an apparatus in accordance with the present invention.

FIG. 8 shows a transverse top view of the embodiment of FIG. 7.

FIG. 9 shows a longitudinal top cross sectional view of the embodiment of FIG. 7.

FIG. 10 shows a longitudinal side cross sectional view of the embodiment of FIG. 7.

FIG. 11 shows a longitudinal top view of the embodiment of FIG. 7.

FIG. 12 is a side cross-sectional view of the embodiment of FIG. 7.

### DETAILED DESCRIPTION

The present invention relates in general to an apparatus and method for the production of carbon nanotubes on a continuously moving substrate. In accordance with some embodiments, apparatus 100 is used to grow, produce, deposit, or otherwise generate CNTs in situ directly onto or into moving substrate 106 and takes the form of an open ended, atmospheric, to slightly higher than atmospheric pressure, small cavity, chemical vapor deposition (CVD) CNT growth system. In accordance with the illustrative embodiment, CNTs are grown via CVD at atmospheric pressure and at elevated temperature (typically in the range of about 550° C. to about 800° C. in a multi-zone apparatus 100. The fact that the synthesis occurs at atmospheric pressure is one factor that facilitates the incorporation of apparatus 100 into a continuous processing line for CNT-on-fiber synthesis. The fact that CNT growth occurs in a seconds, as opposed to minutes (or longer) in the prior art, is another feature that enables using the apparatus disclosed herein in a continuous processing line. CNT-synthesis can be performed at a rate sufficient to provide a continuous process for functionalizing spoolable substrates. Numerous apparatus configurations facilitate such continuous synthesis.

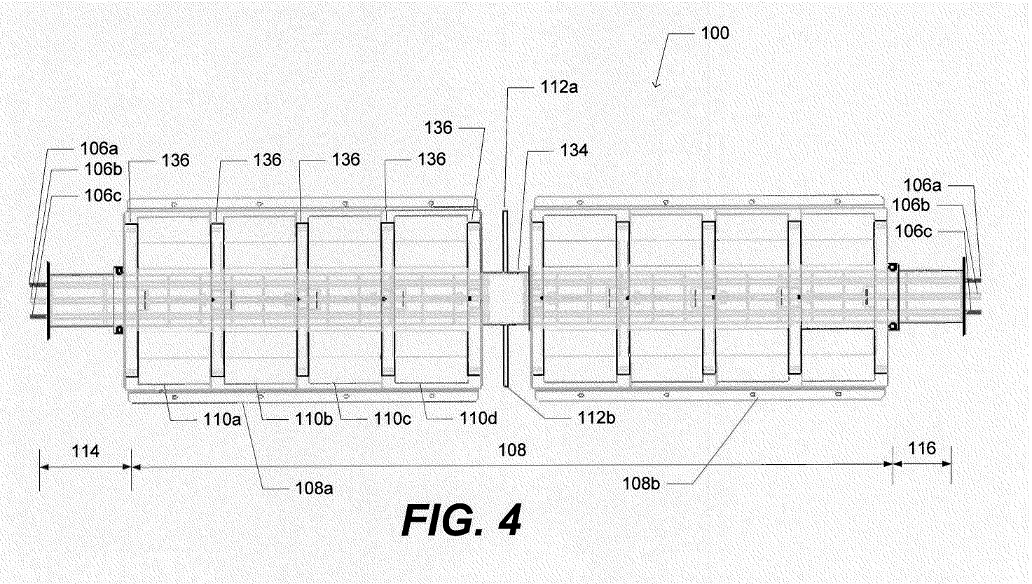

Apparatus 100 includes at least one CNT growth zone 108 equipped with growth heaters 110 disposed between two quench or purge zones 114, 116. Any number of growth heaters can be included, (e.g., heaters 110a, 110b, 110c, 110d of FIG. 4). Apparatus 100 optionally includes pre-heater 132 that pre-heats feed gas 128 and feed gas diffuser 136 to distribute feed gas 128.

In order to realize the potential enhancements afforded by CNT introduction into various materials and applications, an apparatus for applying CNTs directly to substrate surfaces is disclosed herein. CNTs applied directly on substrate surfaces, particularly in the case of silicon wafers or composite fiber materials, improves overall CNT dispersion, placement, and alignment in the completed structure. In the case of composite materials, the incorporation of CNTs on the fiber or fabric level improves CNT loading by having the CNTs preordered and placed in the composite structure, instead of having to dope resins with loose CNTs. To grow CNTs directly on a substrate in a continuous process improves not only these physical characteristics but also reduces overall CNT cost. By having CNTs grown directly on the final useful substrate surface, the auxiliary costs involved with CNT purification and doping/mixing/placement/dispersion are removed.

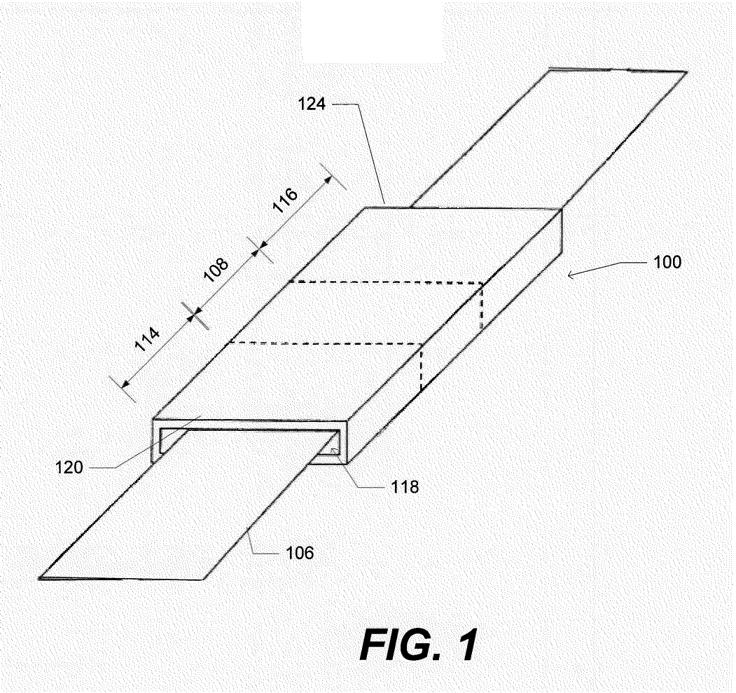

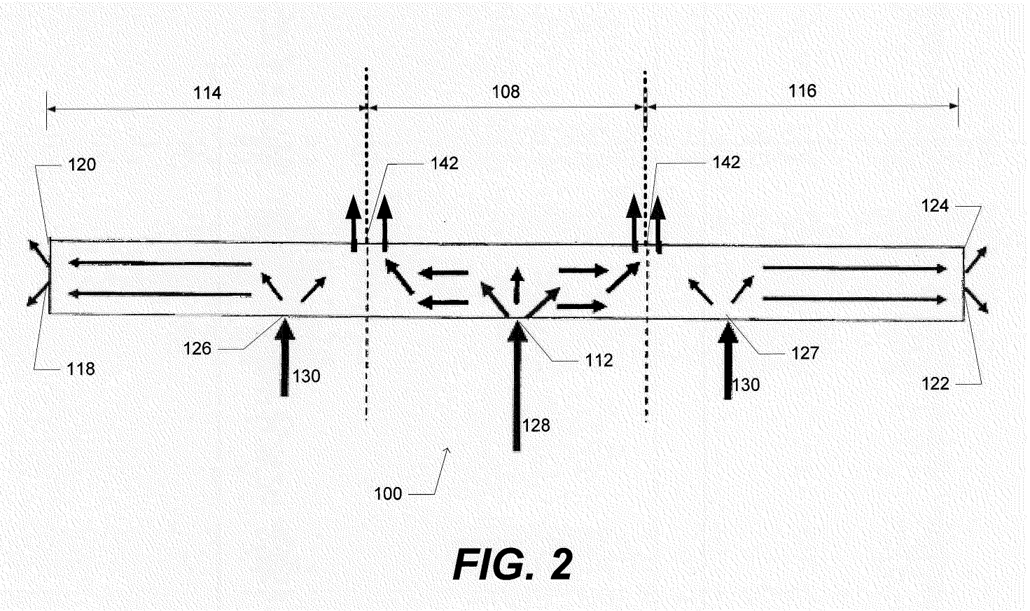

Referring to FIG. 1, apparatus 100 can include substrate inlet 118 sized to allow spoolable length substrate 106 to continually pass therethrough, allowing for the synthesis and growth of CNTs directly on substrate 106. Apparatus 100 can be a multi-zone apparatus with seed or CNT growth zone 108 between a pre-process purge or first purge zone 114 and a post-process purge or second purge zone 116. Apparatus 100 can be open to the atmosphere during operation, with first end 120 and second end 124, such that substrate 106 enters apparatus 100 through substrate inlet 118 in first end 120, passes through first purge zone 114, CNT growth zone 108, second purge zone 116 and out through substrate outlet 122 (shown in FIG. 2) in second end 124. In some embodiments, the CNT growth system can include additional zones that are specifically designed to activate catalyst particles via reduction reactions. In such embodiments, a catalyst activation zone can be placed between first purge zone 114 and CNT growth zone 108.

Apparatus 100 allows for the seamless transfer of substrate 106 into and out of CNT growth zone 108, obviating the need for batch runs. Spoolable length substrate 106 effectively passes through an equilibrated growth system which has established optimal conditions for rapid CNT growth in real time as substrate 106 continually moves through a system that begins with spoolable length substrate 106 and winds the finished product at the end at CNT infusion on substrate 106. The ability to do this continuously and efficiently, while controlling parameters such as CNT length, density, and other characteristics has not been previously achieved.

In some embodiments, a continuous process for infusion of CNTs on spoolable substrates can achieve a linespeed between about 0.5 ft/min to about 36 ft/min. In this embodiment where CNT growth zone 108 is 3 feet long and operating at a 750° C. growth temperature, the process can be run with a linespeed of about 6 ft/min to about 36 ft/min to produce, for example, CNTs having a length between about 1 micron to about 10 microns. The process can also be run with a linespeed of about 1 ft/min to about 6 ft/min to produce, for example, CNTs having a length between about 10 microns to about 100 microns. The process can be run with a linespeed of about 0.5 ft/min to about 1 ft/min to produce, for example, CNTs having a length between about 100 microns to about 200 microns. The CNT length is not tied only to linespeed and growth temperature, however, the flow rate of both the feed gas and inert carrier gases can also influence CNT length. For example, a flow rate consisting of less than 1% carbon feedstock in inert gas at high linespeeds (6 ft/min to 36 ft/min) will result in CNTs having a length between 1 micron to about 5 microns. A flow rate consisting of more than 1% carbon feedstock in inert gas at high linespeeds (6 ft/min to 36 ft/min) will result in CNTs having length between 5 microns to about 10 microns. Resulting growth rates for this continuous CNT growth system range depending on temperature, gases used, substrate residence time, and catalyst, however, growth rates on the range of 0.01-10 microns/second are possible.

CNT growth zone 108 can be an open-air continuous operation, flow-through chamber. CNT growth zone 108 can be formed or otherwise bound by a metal enclosure such as stainless steel, titanium, carbon steel, or other high temperature metal or mixtures thereof, with additional features added to improve structural rigidity as well as reduce thermal warping due to repeated heat cycling. CNT growth zone 108 can be circular, rectangular, oval, or any number of polygonal or other geometrical variant cross-section based on the profile and size of substrate passing therethrough.

An internal volume of CNT growth zone 108 can be compared with a volume of substrate 106 having a length substantially equal to a length of CNT growth zone 108. In some embodiments, CNT growth zone 108 is designed to have an internal volume of no more than about 10000 times greater than the volume of substrate 106 disposed within CNT growth zone 108. In most embodiments, this number is greatly reduced to no more than about 4000 times. In other embodiments, this can be reduced to about 3000 times or less. Similarly, cross sectional areas of CNT growth zone 108 can be limited to about 10000, 4000, or 3000 times greater than a cross sectional area of substrate 106. Without being bound by theory, reducing the size of CNT growth zone 108 ensures high probability interactions between feed gas 128 and substrates coated with catalyst particles. Larger volumes result in excessive unfavorable reactions as the treated substrate is only a small fraction of the available volume. CNT growth zone 108 can range from dimensions as small as millimeters wide to as large as over 1600 mm wide. CNT growth zone 108 can have a rectangular cross-section and a volume of about 0.27 cubic feet. Temperature in CNT growth zone 108 can be controlled with imbedded thermocouples strategically placed on an interior surface thereof. Since CNT growth zone 108 is so small, the temperature of the enclosure is nearly the same temperature as the CNT growth zone 108 and gases inside. CNT growth zone 108 can be maintained at about 550° C.

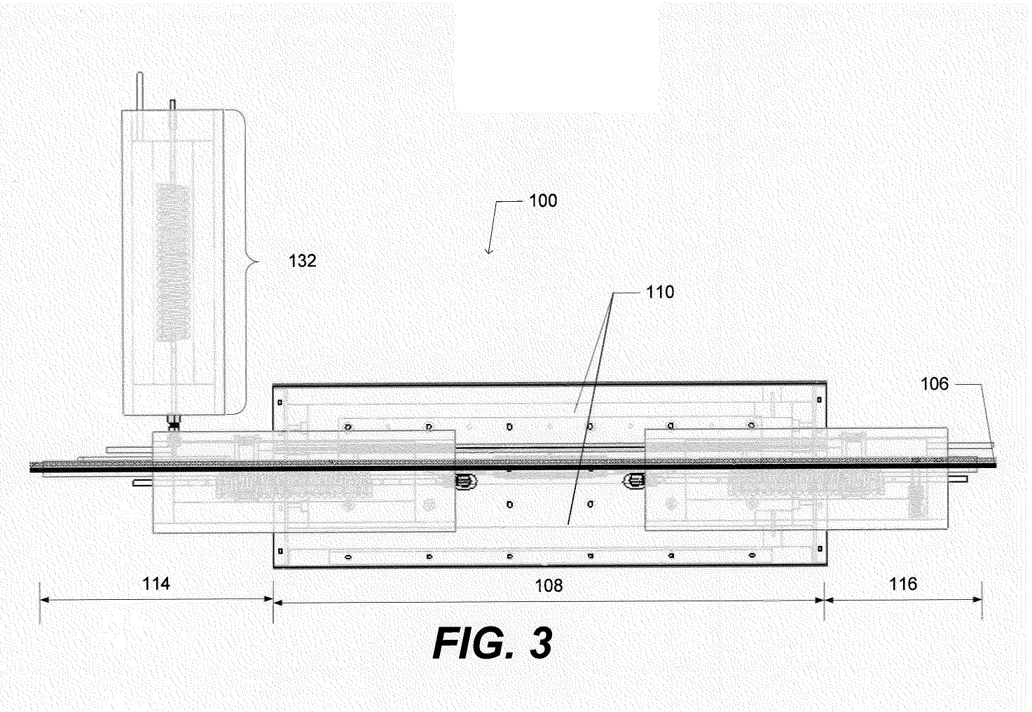

Referring now to FIG. 2, FIG. 3, and FIG. 4, both purge zones 114, 116 provide the same function. As feed gas 128 (shown in FIG. 2) from CNT growth zone 108 exits apparatus 100, purge zones 114, 116 supply a continuous flow of purge gas 130 (shown in FIG. 2) to buffer CNT growth zone 108 from the external environment. This can include optionally preheating purge zone 114 and/or cooling purge zone 116. This helps to prevent unwanted mixing of feed gas 128 with the outside atmosphere, which could cause unintended oxidation and damage to substrate 106 (shown in FIG. 3 and FIG. 4) or CNT material. Purge zones 114, 116 are insulated from CNT growth zone 108 to prevent excessive heat loss or transfer from heated CNT growth zone 108. In some embodiments, one or more exhaust ports 142 (shown in FIG. 2) are placed between purge zones 114, 116 and CNT growth zone 108. In such embodiments, gas does not mix between CNT growth zone 108 and purge zones 114, 116, but instead exhausts to the atmosphere through ports 142. This also prevents gas mixing which is important in situations where multiple CNT growth zones 108 (e.g., 108a, 108b in FIG. 4) can be used in series, attached, or otherwise utilized together to extend the overall effective CNT growth zone. Purge zones 114, 116 in this embodiment still provide a cool gas purge to ensure reduced temperatures as substrate 106 enters/exits CNT growth zone 108.

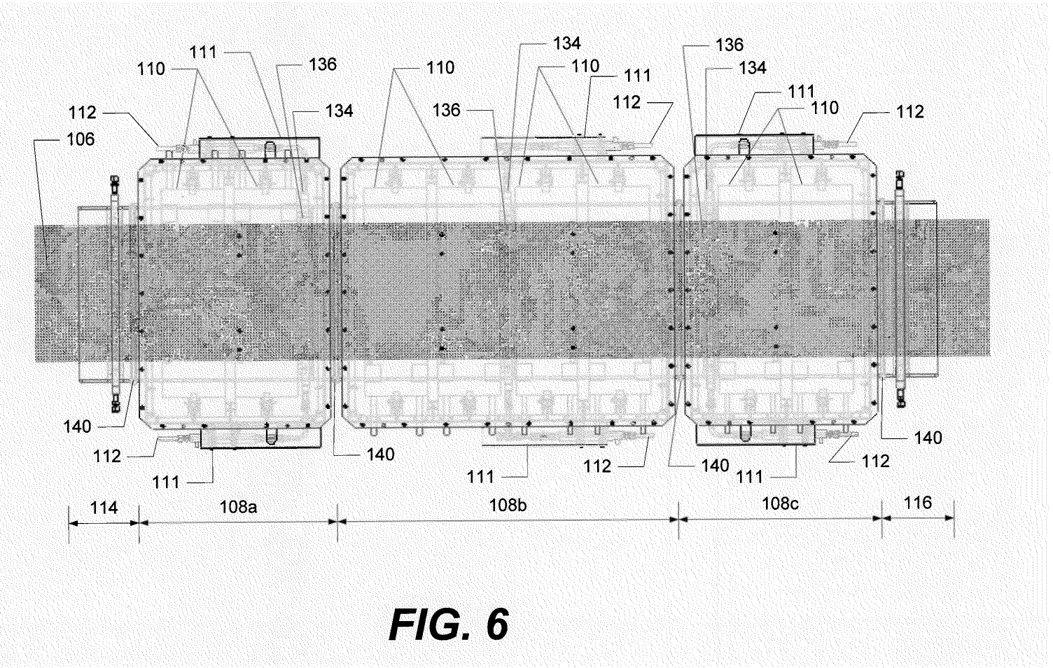

Feed gas 128 can enter CNT growth zone 108 of apparatus 100 via one or more feed gas inlets 112 (e.g., 112a and 112b of FIG. 4). Feed gas 128 can pass through feed gas inlet manifold 134 (shown in FIG. 4) and into CNT growth zone 108 via feed gas diffusers 136 (shown in FIG. 4). Feed gas 128 can react with seeds present on or in substrate 106 to create CNTs, with any leftover feed gas 128 passing through exhaust manifold 140 (shown in FIG. 6) or otherwise exit CNT growth zone 108. Purge gas 130 can be used to prevent the hot gases inside CNT growth zone 108 from mixing with the oxygen rich gas outside CNT growth zone 108 and creating local oxidizing conditions that could adversely affect substrate 106 entering or exiting CNT growth zone 108. Purge gas 130 can enter purge zones 114, 116 of apparatus 100 at purge gas inlets 126, 127 (shown in FIG. 2), allowing for a buffer between CNT growth zone 108 and the external environment. Purge gas 130 can prevent ambient gasses from entering CNT growth zone 108, and can either exit through substrate inlet 118 or substrate outlet 122 at respective ends 120, 124 of apparatus 100 as indicated in FIG. 2, or purge gas 130 can exit through exhaust manifold 140 (shown in FIG. 6).

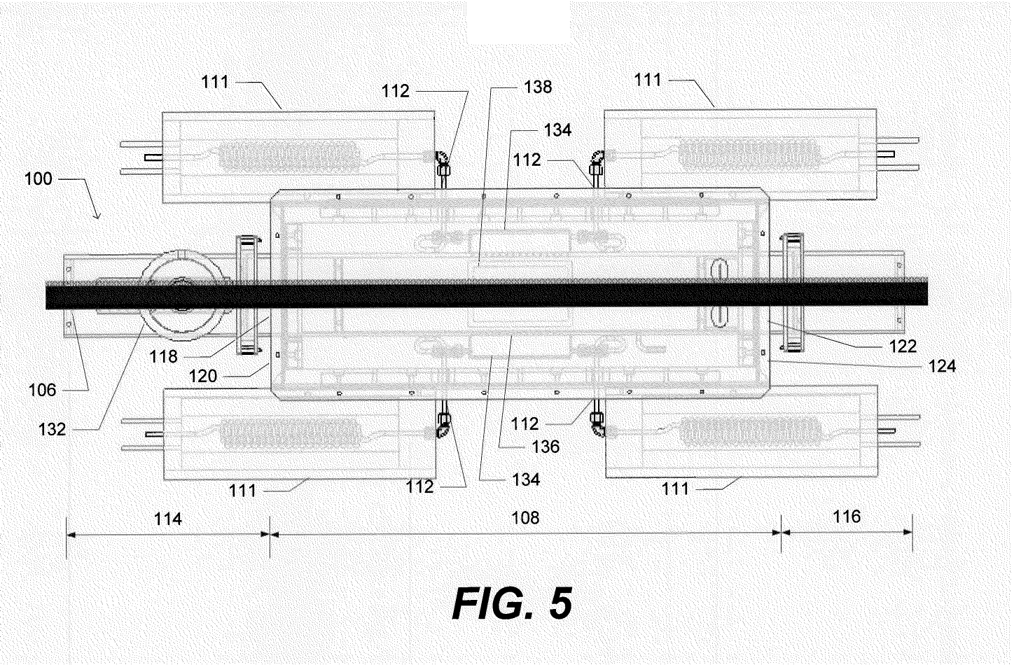

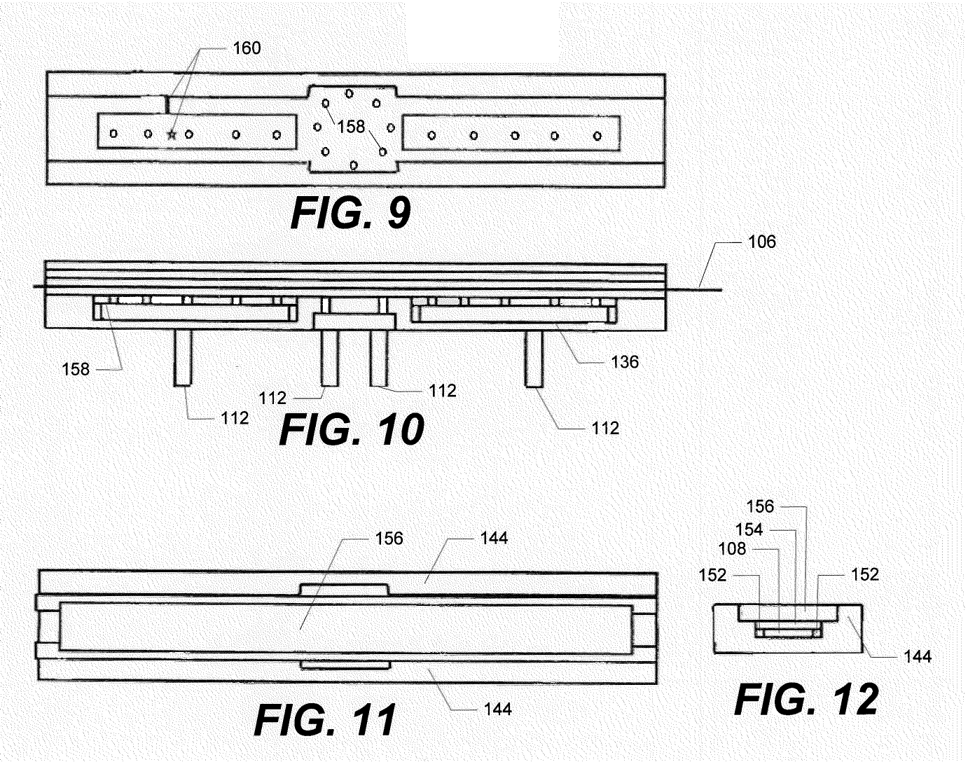

Purge gas preheater 132 (shown in FIG. 3) can preheat purge gas 130 prior to introduction into first purge zone 114. CNT growth zone 108 can be further heated by heaters 110 (shown in FIG. 3) contained within CNT growth zone 108. As illustrated, heaters 110 are on either side of substrate 106. However, heaters 110 can be anywhere within CNT growth zone 108, either placed along the length or in cases of wide systems, along the width of CNT growth zone 108, to ensure isothermal heating for well controlled CNT growth processes. Heaters 110 can heat CNT growth zone 108 and maintain an operational temperature at a pre-set level. Heaters 110 can be controlled by a controller (not shown). Heaters 110 can be any suitable device capable of maintaining CNT growth zone 108 at about the operating temperature. Alternatively, or additionally, heaters 111 (shown in FIG. 5 and FIG. 6) can preheat feed gas 128. Any of heaters 110, 111, 132 can be used in conjunction with CNT growth zone 108, so long as the particular heater is in thermal communication with CNT growth zone 108. Heaters 110, 111, 132 can include long coils of gas line heated by a resistively heated element, and/or series of expanding tubes to slow down and which is then heated via resistive heaters (e.g., infrared heaters). Regardless of the method, gas can be heated from about room temperature to a temperature suitable for CNT growth, e.g. from about 25° C. to about 800° C. In some instances, heaters 110, 111, and/or 132 can provide heat such that the temperature within CNT growth zone 108 is about 550° C. to about 850° C. or up to about 1000° C. Temperature controls (not shown) can provide monitoring and/or adjustment of temperature within CNT growth zone 108. Measurement can be made at points (e.g., probe 160 of FIG. 9) on plates or other structures defining CNT growth zone 108. Because the height of CNT growth zone 108 is relatively small, the temperature gradient between the plates can be very small, and thus, measurement of temperature of the plates can accurately reflect the temperature within CNT growth zone 108.

Because substrate 106 has a small thermal mass, as compared with CNT growth zone 108, substrate 106 can assume the temperature of CNT growth zone 108 almost immediately. Thus, preheat can be left off to allow room temperature gas to enter the growth zone for heating by heaters 110. In some embodiments, only purge gas is preheated. Other feed gas can be added to purge gas after purge gas preheater 132. This can be done to reduce long term sooting and clogging conditions that can occur in purge gas preheater 132 over long times of operations. Preheated purge gas can then enter feed gas inlet manifold 134.

Feed gas inlet manifold 134 provides a cavity for further gas mixing as well as a means for dispersing and distributing gas to all gas insertion points in CNT growth zone 108. These points of insertion are built into one or more feed gas diffusers 136, e.g. gas diffuser plates with a series of patterned holes. These strategically placed holes ensure a consistent pressure and gas flow distribution. Feed gas enters CNT growth zone 108, where heaters 110 can apply an even temperature generation source.

Referring now to FIG. 5, in one exemplary embodiment, substrate 106 enters first purge zone 114, where purge gas 130, which has been preheated by purge gas preheater 132 warms substrate 106 while simultaneously preventing ambient air from entering CNT growth zone 108. Substrate 106 then passes through substrate inlet 118 in first end 120 of CNT growth zone 108. As illustrated in FIG. 5 and FIG. 6, substrate 106 enters CNT growth zone 108, is heated by heaters 110 (shown in FIG. 6) and exposed to feed gas 128 (shown in FIG. 2). Before entering CNT growth zone 108, feed gas 128 can move from any of heaters 111, through any of feed gas inlets 112, through feed gas inlet manifold 134, and through feed gas diffusers 136. Feed gas 128 and/or purge gas 130 can exit first purge zone 114 and/or CNT growth zone 108 via exhaust ports 142 and/or exhaust manifold 140, maintaining atmospheric or slightly above atmospheric pressure. Substrate 106 can continue through additional CNT growth zones 108 as desired until sufficient CNT growth has occurred. As illustrated in FIG. 5, substrate 106 passes through substrate outlet 122 in second end 124 of CNT growth zone 108 and into second purge zone 116. Alternatively, first purge zone 114 and second purge zone 116 can be the same zone and substrate 106 can turn around within apparatus 100 and pass out of CNT growth zone 108 via substrate inlet 118. In either event, substrate passes into a purge zone and out of apparatus 100. Purge zones 114 and 116 can each have purge gas introduced through purge gas inlet 126 and 127 (shown in FIG. 2), such that purge gas 130 therein acts as a buffer and prevents feed gas 128 from contacting ambient air. Likewise, Purge zones 114 and 116 can each have exhaust ports 142 (shown in FIG. 2) and/or exhaust manifolds 140 (shown in FIG. 6) to accomplish appropriate buffering. Access plate 138 (shown in FIG. 5) can provide access to CNT growth zone 108, for cleaning and other maintenance.

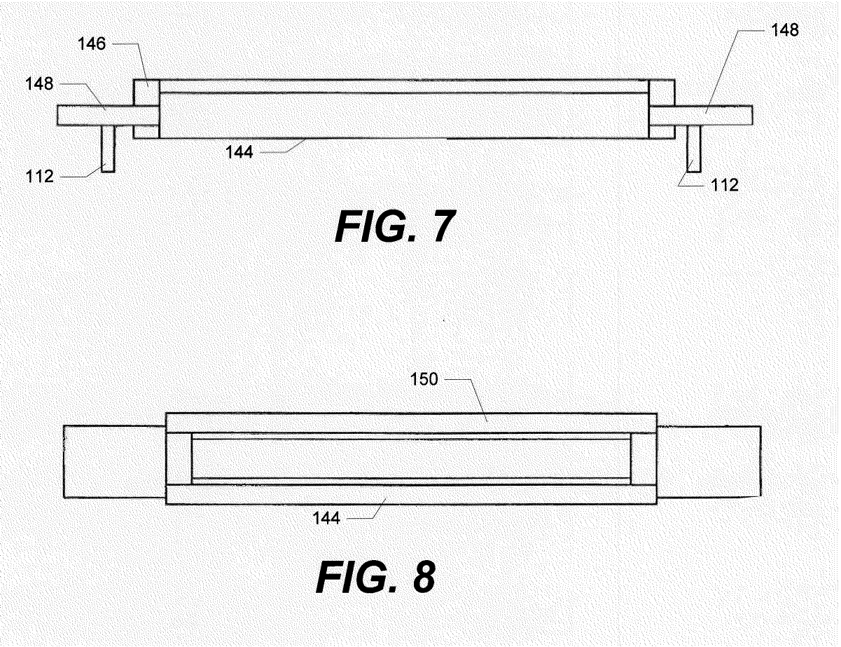

Referring now to FIGS. 7-12, in one embodiment, CNT growth zone 108 can be constructed from skirt 144, piped connection 146, and plugged connection 148. Insulation, such as gas seal insulation 150 can provide a barrier to the external environment. Stainless steel standoffs 152 can support copper plate 154, which can in turn support quartz lens 156. As with the embodiments described above, feed gas can enter CNT growth zone 108 via gas ports 158 and temperature can be monitored by probe 160. While the embodiment illustrated in FIGS. 7-12 is functional, the embodiments described above are preferred at the time of filing.

In some embodiments, multiple substrates 106 (e.g., 106a, 106b, 106 c in FIG. 4) can pass through apparatus 100 at any given time. Likewise, any number of heaters can be used either inside or outside a particular CNT growth zone 108.

Some of potential advantages of the apparatus and method of the present teachings can include, without limitation: improved cross-sectional area; improved zoning; improved materials; and combined catalyst reduction and CNT synthesis.

Since most of the material processed is relatively planar (e.g., flat tape or sheet-like form), the conventional circular cross-section is an inefficient use of volume. Such circular cross-section can create difficulties with maintaining a sufficient system purge, because an increased volume requires increased purge gas flow rates to maintain the same level of gas purge. Thus, the conventional circular cross-section is inefficient for high volume production of CNTs in an open environment. Further such circular cross-section can create a need for increased feed gas flow. The relative increase in purge gas flow requires increased feed gas flows. For example, the volume of a 12K fiber is 2000 times less than the total volume of exemplary CNT growth zone 108 having a rectangular cross-section. In an equivalent growth cylindrical chamber (e.g., a cylindrical chamber having a width that accommodates the same planarized fiber as the rectangular cross-section CNT growth zone 108), the volume of the fiber is 17,500 times less than the volume of CNT growth zone 108. Although gas deposition processes (e.g., CVD, etc.) are typically governed by pressure and temperature alone, volume has a significant impact on the efficiency of deposition. With illustrative rectangular CNT growth zone 108 there is quite a bit of excess volume—volume in which unwanted reactions occur (e.g., gasses reacting with themselves or with chamber walls); and a cylindrical chamber has about eight times that volume. Due to this greater opportunity for competing reactions to occur, the desired reactions effectively occur more slowly in a cylindrical chamber, which is problematic for the development of a continuous process. Additionally, it is notable that when using a cylindrical chamber, more feed gas is required to provide the same flow percent as in the illustrative CNT growth zones having a rectangular cross-section. Another problem with the conventional circular cross-section is temperature distribution. When a relatively small-diameter chamber is used, the temperature gradient from the center of the chamber to the walls thereof is minimal. But with increased size, such as would be required for commercial-scale production, the temperature gradient increases. Such temperature gradients result in product quality variations across a substrate (i.e., product quality varies as a function of radial position). This problem is substantially avoided when using CNT growth zone 108 having a cross-section more closely matched to corresponding substrate 106 (e.g., rectangular). In particular, when a planar substrate is used, CNT growth zone 108 can have a height maintained constant as the size of substrate 106 scales upward. Temperature gradients between the top and bottom of CNT growth zone 108 are essentially negligible and, consequently, thermal issues and the product-quality variations that result are avoided.

The conventional circular cross-sectional chamber also requires feed gas introduction. Because tubular furnaces are used, conventional CNT synthesis chambers introduce feed gas at one end and draw it through the chamber to the other end. In the illustrative embodiment disclosed herein, feed gas is introduced at the center of or within CNT growth zone 108 (symmetrically, either through the sides or through the top and bottom plates of CNT growth zone 108). This improves the overall CNT growth rate because the incoming feed gas in continuously replenishing at the hottest portion of the system, which is where CNT growth is most active. This constant feed gas replenishment can be an important aspect to the increased growth rate exhibited by CNT growth zone(s) 108 in accordance with the present teachings.

When hot feed gas mixes with the external environment, degradation of the substrate material (e.g., fiber) would increase. Conventional CNT synthesis processes typically require that the substrate is carefully (and slowly) cooled. Purge zones 114, 116 on either or both ends of CNT growth zone 108 disclosed herein provide a buffer between the internal system and external environments. Purge zone 116 achieves the cooling in a short period of time, as may be required for the continuous processing line.

The use of metal (e.g., stainless steel) in accordance with the illustrative embodiment is uncommon and, in fact, counterintuitive. Metal, and stainless steel in particular, is more susceptible to carbon deposition (i.e., soot and by-product formation). Quartz, on the other hand, is easier to clean, with fewer deposits. Quartz also facilitates sample observation. However, the increased soot and carbon deposition on stainless steel can result in more consistent, faster, more efficient, and more stable CNT growth. It is believed that, in conjunction with atmospheric operation, the CVD process occurring in CNT growth zone 108 is diffusion limited. That is, the catalyst is “overfed;” too much carbon is available in the system due to its relatively higher partial pressure (than if operating under partial vacuum). As a consequence, in an open system—especially a clean one—too much carbon can adhere to catalyst particles, compromising their ability to synthesize CNTs. In accordance with the illustrative embodiment, the inventors thus intentionally run the apparatus “dirty.” Once carbon deposits to a monolayer on the walls of CNT growth zone 108, carbon will readily deposit over itself. Since some of the available carbon is “withdrawn” due to this mechanism, the remaining carbon radicals react with the catalyst at a more acceptable rate—a rate that does not poison the catalyst. Existing systems run “cleanly” which, if they were open for continuous processing, would produced a much lower yield of CNTs at reduced growth rates.

Using apparatus 100 allows for both a catalyst reduction and CNT growth to occur within CNT growth zone 108. This is significant because the reduction step cannot be accomplished timely enough for use in a continuous process if performed as a discrete operation. Conventionally, the reduction step typically takes 1-12 hours to perform. Both operations occur in CNT growth zone 108 in accordance with the present invention due, at least in part, to the fact that feed gas is introduced the center of CNT growth zone 108, not the end. The reduction process occurs as the fibers enter the heated zone; by this point, the gas has had time to react with the walls and cool off prior to reacting with the catalyst and causing the oxidation reduction (via hydrogen radical interactions). It is this transition region where the reduction occurs. At the hottest isothermal zone in the system, the CNT growth occurs, with the greatest growth rate occurring proximal to the feed gas inlets near the center of the CNT growth zone.

The illustrative embodiments can be used with any type of substrate. The term “substrate” is intended to include any material upon which CNTs can be synthesized and can include, but is not limited to, a carbon fiber, a graphite fiber, a cellulosic fiber, a glass fiber, a metal fiber (e.g., steel, aluminum, etc.), a metallic fiber, a ceramic fiber, a metallic-ceramic fiber, an aramid fiber, or any substrate comprising a combination thereof. The substrate can include fibers or filaments arranged, for example, in a fiber tow (typically having about 1000 to about 12000 fibers) as well as planar substrates such as fabrics, tapes, or other fiber broadgoods, and materials upon which CNTs can be synthesized.

In some embodiments, the apparatus of the present invention results in the production of carbon-nanotube infused fiber. As used herein, the term “infused” means chemically or physically bonded and “infusion” means the process of bonding. Such bonding can involve direct covalent bonding, ionic bonding, pi-pi, and/or van der Waals force-mediated physisorption. For example, in some embodiments, the CNTs can be directly bonded to the substrate. Additionally, it is believed that some degree of mechanical interlocking occurs as well. Bonding can be indirect, such as the CNT infusion to the substrate via a barrier coating and/or an intervening transition metal nanoparticle disposed between the CNTs and substrate. In the CNT-infused substrates disclosed herein, the carbon nanotubes can be “infused” to the substrate directly or indirectly as described above. The particular manner in which a CNT is “infused” to a substrate is referred to as a “bonding motif.”

CNTs useful for infusion to substrates include single-walled CNTs, double-walled CNTs, multi-walled CNTs, and mixtures thereof. The exact CNTs to be used depends on the application of the CNT-infused substrate. CNTs can be used for thermal and/or electrical conductivity applications, or as insulators. In some embodiments, the infused carbon nanotubes are single-wall nanotubes. In some embodiments, the infused carbon nanotubes are multi-wall nanotubes. In some embodiments, the infused carbon nanotubes are a combination of single-wall and multi-wall nanotubes. There are some differences in the characteristic properties of single-wall and multi-wall nanotubes that, for some end uses of the fiber, dictate the synthesis of one or the other type of nanotube. For example, single-walled nanotubes can be semi-conducting or metallic, while multi-walled nanotubes are metallic.

As is clear from the foregoing, two key distinctions between conventional chambers and illustrative apparatus and method are: catalyst reduction time and CNT synthesis time. In the illustrative methods, these operations take seconds, rather than several minutes to hours as per conventional systems. The inability of conventional chambers to control catalyst-particle chemistry and geometry results in processes that include multiple time-consuming sub operations that can only be performed in batchwise fashion.

In a variation of the illustrative embodiment, the continuous processing line for CNT growth is used to provide an improved filament winding process. In this variation, CNTs are formed on substrates (e.g., graphite tow, glass roving, etc.) using the system and process described above, and are then passed through a resin bath to produce resin-impregnated, CNT-infused substrate. After resin impregnation, the substrate is positioned on the surface of a rotating mandrel by a delivery head. The substrate then winds onto the mandrel in a precise geometric pattern in known fashion. These additional sub operations can be performed in continuous fashion, extending the basic continuous process.

The filament winding process described above provides pipes, tubes, or other forms as are characteristically produced via a male mold. But the forms made from the filament winding process disclosed herein differ from those produced via conventional filament winding processes. Specifically, in the process disclosed herein, the forms are made from composite materials that include CNT-infused substrates. Such forms will therefore benefit from enhanced strength, etc., as provided by the CNT-infused substrates.

As used herein the term “spoolable dimensions” refers to substrates having at least one dimension that is not limited in length, allowing for the material to be stored on a spool or mandrel. Substrates of “spoolable dimensions” have at least one dimension that indicates the use of either batch or continuous processing for CNT infusion as described herein. One substrate of spoolable dimensions that is commercially available is exemplified by AS4 12k carbon fiber tow with a tex value of 800 (1 tex=1 g/1,000 m) or 620 yard/lb (Grafil, Inc., Sacramento, Calif.). Commercial carbon fiber tow, in particular, can be obtained in 5, 10, 20, 50, and 100 lb. (for spools having high weight, usually a 3k/12K tow) spools, for example, although larger spools may require special order. Processes of the invention operate readily with 5 to 20 lb. spools, although larger spools are usable. Moreover, a pre-process operation can be incorporated that divides very large spoolable lengths, for example 100 lb. or more, into easy to handle dimensions, such as two 50 lb spools.

As used herein, the term “feed gas” refers to any carbon compound gas, solid, or liquid that can be volatilized, nebulized, atomized, or otherwise fluidized and is capable of dissociating or cracking at high temperatures into at least some free carbon radicals and which, in the presence of a catalyst, can form CNTs on the substrate. In some embodiments, feed gas can comprise acetylene, ethylene, methanol, methane, propane, benzene, natural gas, or any combination thereof.

As used herein, the term “purge gas” refers to any gas, solid, or liquid that can be volatilized, nebulized, atomized, or otherwise fluidized and is capable of displacing another gas. Purge gas can optionally be cooler than corresponding feed gas. In some embodiments, purge gas can include a mass flow controlled mixture of inert gas such as nitrogen, argon, or helium and carbon feedstock, such as acetylene, ethylene, ethane, methane, carbon monoxide, and similar carbon-containing gases, typically mixed from between about 0 to about 10% feed gas with the remainder consisting of inert gas. In other embodiments, however, additional gases such as ammonia, hydrogen, and/or oxygen can be mixed as a third process gas as well in ranges of between about 0 to about 10%.

As used herein, the term “nanoparticle” or NP (plural NPs), or grammatical equivalents thereof refers to particles sized between about 0.1 to about 100 nanometers in equivalent spherical diameter, although the NPs need not be spherical in shape. Transition metal NPs, in particular, serve as catalysts for CNT growth on the substrates.

As used herein, the term “material residence time” refers to the amount of time a discrete point along a substrate of spoolable dimensions is exposed to CNT growth conditions during the CNT infusion processes described herein. This definition includes the residence time when employing multiple CNT growth zones.

As used herein, the term “linespeed” refers to the speed at which a substrate of spoolable dimensions can be fed through the CNT infusion processes described herein, where linespeed is a velocity determined by dividing CNT growth zone(s) length by the material residence time.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. An apparatus comprising:
at least one carbon nanotube growth zone having a substrate inlet sized to allow a spoolable length substrate to pass therethrough;
at least one heater in thermal communication with the carbon nanotube growth zone; and
at least one feed gas inlet in fluid communication with the carbon nanotube growth zone;
wherein the apparatus is open to the atmosphere during operation.

2. The apparatus of claim 1, comprising a purge zone.

3. The apparatus of claim 1, comprising at least two purge zones on opposing sides of the carbon nanotube growth zone.

4. The apparatus of claim 1, comprising a substrate outlet.

5. The apparatus of claim 1, wherein the feed gas inlet is in the carbon nanotube growth zone.

6. The apparatus of claim 2, comprising a purge gas inlet in the purge zone.

7. The apparatus of claim 1, wherein a cross sectional area of the carbon nanotube growth zone is no greater than about 10000 times a cross sectional area of the spoolable length substrate.

8. The apparatus of claim 1, wherein the carbon nanotube growth zone has an internal volume no greater than about 10000 times a volume of a section of the spoolable length substrate; wherein the section of the spoolable length substrate has a length substantially equal to the length of the carbon nanotube growth zone.

9. The apparatus of claim 1, wherein the carbon nanotube growth zone is formed by an enclosure comprising metal.

10. The apparatus of claim 9, wherein the metal comprises stainless steel.

11. The apparatus of claim 1, comprising at least two carbon nanotube growth zones.

12. A method comprising:
providing an apparatus having at least one carbon nanotube growth zone having a substrate inlet sized to allow a spoolable length substrate to pass therethrough, wherein the apparatus is open to the atmosphere;
providing a substrate;
introducing a portion of the substrate into carbon nanotube growth zone via the inlet;
introducing a feed gas into the carbon nanotube growth zone; and
passing the portion of the substrate through the carbon nanotube growth zone, such that carbon nanotubes form on the portion of the substrate.

13. The method of claim 12, comprising removing the portion of the substrate and carbon nanotubes formed thereon from the carbon nanotube growth zone.

14. The method of claim 12, wherein the steps are performed in the order recited in claim 12.

15. The method of claim 12, wherein the apparatus has at least one purge zone, the method further comprising purging the purge zone prior to introducing the portion of the substrate into the carbon nanotube growth zone.

16. The method of claim 12, further comprising preheating the feed gas prior to introducing the feed gas into the carbon nanotube growth zone.

17. The method of claim 15, wherein the apparatus has comprises an additional purge zone on an opposing side of the carbon nanotube growth zone from the first purge zone, the method further comprising purging the additional purge zone after the portion of the substrate has passed through the carbon nanotube growth zone.

18. The method of claim 12, wherein the apparatus has at least two carbon nanotube growth zones, the method comprising passing the portion of the substrate through each of the carbon nanotube growth zones.

19. The method of claim 12, wherein the substrate is a spoolable length substrate, the method comprising continuously passing the spoolable length substrate through the apparatus.
